(19) United States
(12) Patent Application Publication
(10) Pub. No.: US 2025/0120226 A1
(43) Pub. Date: Apr. 10, 2025

(54) Display Apparatus

(71) Applicant: LG Display Co., Ltd., Seoul (KR)

(72) Inventors: Bogyun Chung, Goyang-si (KR); Seok Kim, Seoul (KR); Yoonseok Kim, Paju-si (KR); Jaekyung Lee, Paju-si (KR); Hyeonho Son, Goyang-si (KR); Seungman Ryu, Paju-si (KR); Jungeun Son, Goyang-si (KR)

(21) Appl. No.: 18/819,985

(22) Filed: Aug. 29, 2024

(30) Foreign Application Priority Data
Oct. 6, 2023 (KR) 10-2023-0133084

(51) Int. Cl. H01L 33/48; H01L 25/16; H01L 33/60; H01L 33/62

(52) U.S. Cl. CPC H10H 20/8506; H01L 25/167; H10H 20/857; H10H 20/856

(57) ABSTRACT

A display apparatus presented herein includes a substrate having a pixel, a light-emitting diode in the pixel, a first insulating layer around the light-emitting diode, a second insulating layer on the first insulating layer, and a first bank around the second insulating layer.

### CROSS-REFERENCE TO RELATED APPLICATION

This application claims the priority from Republic of Korea Patent Application No. 10-2023-0133084, filed on Oct. 6, 2023, which is hereby incorporated by reference in its entirety.

### BACKGROUND

### Field

The present disclosure relates to a display apparatus, and more specifically, to a display apparatus including a light-emitting diode.

### Description of Related Art

In addition to a display screen of a television or a monitor, a display apparatus is widely used as a display screen for laptop computers, tablet computers, smart phones, portable display devices, and portable information devices. Each of a liquid crystal display device and an organic light-emitting display device displays an image using a thin-film transistor as a switching element. Due to presence of a backlight unit, the liquid crystal display device has design limitations, and lowered luminance and response speed. Because the organic light-emitting display device contains an organic material, the organic light-emitting display device is vulnerable to moisture, thereby reducing reliability and a lifespan thereof.

Recently, research and development on a light-emitting diode display device using a micro light-emitting diode are in progress. The light-emitting diode display device is in the spotlight as a next-generation display device because the light-emitting diode display device has high image quality and high reliability.

### SUMMARY

The light-emitting diode display device may have a stain on a display panel due to a difference between luminance levels of front and side surfaces of the display panel. Furthermore, a P/N electrode structure of the light-emitting diode may cause asymmetry in the luminance level in left and right beam angles. Furthermore, due to a tolerance in a manufacturing process of the light-emitting diode, non-uniformity of a viewing angle depending on a position of the light-emitting diode increases.

Thus, a purpose of the present disclosure is to provide a display apparatus with reduced luminance non-uniformity based on a viewing angle to solve the above-mentioned problem.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display apparatus according to one or more embodiments of the present disclosure in order to achieve the purpose may include a substrate that includes a pixel; a light-emitting diode in the pixel; a first insulating layer around the light-emitting diode; a second insulating layer on the first insulating layer; and a first bank around the second insulating layer.

Specific details of other embodiments are included in the detailed description and drawings.

The technical solutions according to one or more embodiments of the present disclosure are not limited to those as mentioned above. Other technical solutions not mentioned above may be clearly understood by those skilled in the art from following descriptions set forth below.

According to the present disclosure, the bank may be disposed around the light-emitting diode to absorb a light beam among light beams emitted from the light-emitting diode that has a small emission direction angle relative to an upper surface of a substrate and thus is directed toward a side surface of the display apparatus, thus reducing a visibility difference caused by reflected light. Accordingly, luminance deviation based on the viewing angle of the display apparatus may be reduced.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF THE DRAWINGS

FIG. 1 is a configuration diagram of a display apparatus according to one or more embodiments of the present disclosure.

FIG. 2 is a perspective view of a tiling display apparatus according to one or more embodiments of the present disclosure.

FIG. 3 is a plan view of a display apparatus according to one or more embodiments of the present disclosure.

FIG. 4 is a plan view of a display apparatus according to one or more embodiments of the present disclosure.

FIG. 5 is a plan view of a display apparatus according to one or more embodiments of the present disclosure.

FIG. 6 is a plan view of a display apparatus according to one or more embodiments of the present disclosure.

FIG. 7 is a plan view of a display apparatus according to one or more embodiments of the present disclosure.

FIG. 8 is a cross-sectional view of a display apparatus according to one or more embodiments of the present disclosure.

FIG. 9 is a cross-sectional view of a display apparatus according to one or more embodiments of the present disclosure.

FIG. 10 is a cross-sectional view of a display apparatus according to one or more embodiments of the present disclosure.

FIG. 11 is a cross-sectional view of a display apparatus according to one or more embodiments of the present disclosure.

FIG. 12 is an enlarged cross-sectional view of a display apparatus according to one or more embodiments of the present disclosure.

FIGS. 13 to 15 are diagrams showing a luminance level based on a viewing angle of a display apparatus according to one or more embodiments of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure embodiments of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “couples to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section as described under could be termed a second element, component, region, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments of the present disclosure may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any embodiment or design as described is superior to or advantageous over other embodiments or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure not limited to the scale as shown in the drawings.

“At least one” should be understood to include any combination of one or more of listed components. For example, at least one of first, second, and third components means not only a first, second, or third component, but also all combinations of two or more of the first, second, and third components.

Hereinafter, the present disclosure will be described with reference to the drawings.

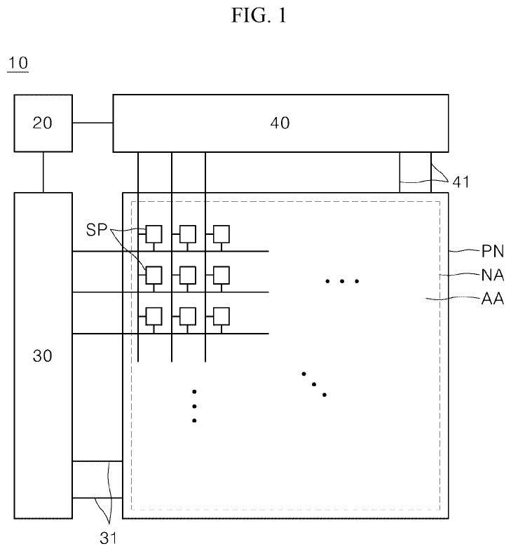

FIG. 1 is a configuration diagram of a display apparatus according to one or more embodiments of the present disclosure.

Referring to FIG. 1, a display apparatus 10 may include a display panel PN including a plurality of sub-pixels SP, a gate driver 30 and a data driver 40 that supply various signals to the display panel PN, and a timing controller 20 that controls the gate driver 30 and the data driver 40.

The gate driver 30 supplies a plurality of scan signals to a plurality of gate lines 31 according to a plurality of gate control signals provided from the timing controller 20. In FIG. 1, one gate driver 30 is shown as being disposed on and spaced apart from one side of the display panel PN. However, the number and arrangement of gate drivers 30 are not limited thereto.

The data driver 40 converts image data input from the timing controller 20 into a data voltage using a reference gamma voltage according to a plurality of data control signals provided from the timing controller 20. The data driver 40 may supply the converted data voltage to a plurality of data lines 41.

The timing controller 20 aligns the image data input from an external source and supplies the aligned data to the data driver 40. The timing controller 20 may generate a gate control signal and a data control signal using a synchronization signal input from an external source, for example, a dot clock signal, a data enable signal, and a horizontal/vertical synchronization signal. The timing controller 20 may supply the generated gate control signal and the generated data control signal to the gate driver 30 and the data driver 40, respectively to control the gate driver 30 and the data driver 40.

The display panel PN is a component for displaying an image to a user, and includes the plurality of sub-pixels SP. In the display panel PN, the plurality of gate lines 31 and the plurality of data lines 41 intersect each other, and each of the plurality of sub-pixels SP is connected to the gate line 31 and the data line 41. Although not shown in FIG. 1, each of the plurality of sub-pixels SP may be connected to a high-potential voltage line, a low-potential voltage line, a reference voltage line, etc.

A display area AA and a non-display area NA surrounding the display area AA may be defined in the display panel PN.

The display area AA is an area where an image is displayed in the display apparatus 10. A plurality of sub-pixels SP constituting each of a plurality of pixels PX and a circuit for driving the plurality of sub-pixels SP may be disposed in the display area AA. Each of the plurality of sub-pixels SP refers to a minimum unit that constitutes the display area AA, and n sub-pixels SP may constitute one pixel PX. A light-emitting element and a thin-film transistor for driving the light-emitting element may be disposed in each of the plurality of sub-pixels SP. A type of each of a plurality of light-emitting elements may vary depending on a type of the display panel PN. For example, the light-emitting element may be embodied as a light-emitting diode (LED) or a micro light-emitting diode (micro-LED).

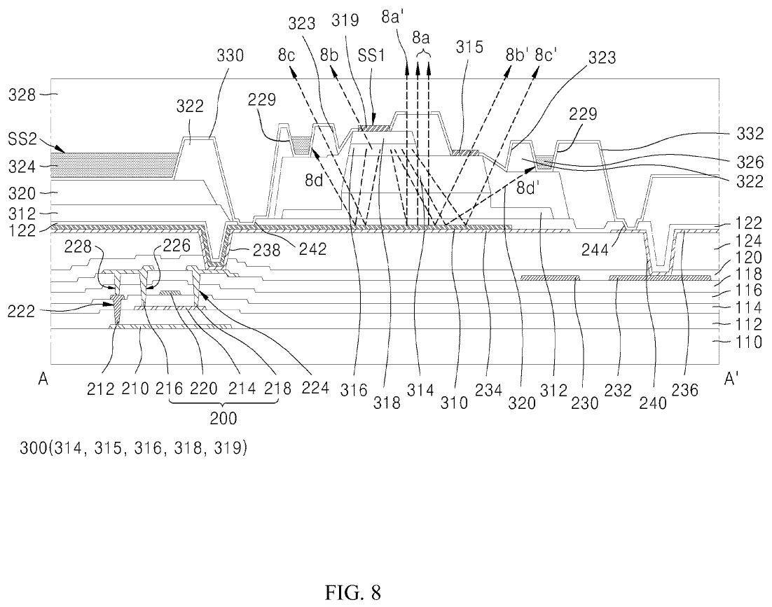

In the display area AA, a plurality of signal lines that transmits various signals to the plurality of sub-pixels SP is disposed. For example, the plurality of signal lines may include the plurality of data lines 41 which supply the data voltage to each of the plurality of sub-pixels SP, and the plurality of gate lines 31 that supply the gate voltage to each of the plurality of sub-pixels SP, etc. The plurality of gate lines 31 may extend in one direction in the display area AA and may be connected to the plurality of sub-pixels SP, and the plurality of data lines 41 may extend in a direction different from the one direction in the display area AA, and may be connected to the plurality of sub-pixels SP. In addition, a second power line 230 (see FIG. 8), a first power line 232 (see FIG. 8), etc. may be further disposed in the display area AA. However, embodiments of the present disclosure are not limited thereto.

The non-display area NA is an area where an image is not displayed and may be defined as an area extending from the display area AA. In the non-display area NA, a link line and a pad electrode to transmit signals to the sub-pixel SP of the display area AA, or driver ICs such as a gate driver IC and a data driver IC may be disposed. In one example, the non-display area NA may be located on a back surface of the display panel PN, that is, on a surface thereof in which the sub-pixels SP are absent, or may be omitted. However, the present disclosure is not limited to what is shown in FIG. 1.

The drivers such as the gate driver 30, the data driver 40, and the timing controller 20 may be connected to the display panel PN in various schemes. For example, the gate driver 30 may be mounted in a GIP (Gate In Panel) scheme in the non-display area NA, or may be installed between the plurality of sub-pixels SP in the display area AA in a GIA (Gate In Active Area) scheme. For example, the data driver 40 and the timing controller 20 may be formed in a separate flexible film and printed circuit board, and the flexible film and the printed circuit board may be bonded to the pad electrode formed in the non-display area NA of the display panel PN and thus the data driver 40 and the timing controller 20 may be electrically connected to the display panel PN. When the gate driver 30 is implemented in the GIP scheme and the data driver 40 and the timing controller 20 transmit the signals to the display panel PN via the pad electrode in the non-display area NA, it is necessary to secure an area of the non-display area NA in which the driver 30 and the pad electrode are disposed, such that a bezel size may increase.

Alternatively, the gate driver 30 may be mounted in the display area AA using the GIA scheme, and a side line connecting a signal line of a front surface of the display panel PN to the pad electrode of a back surface of the display panel PN may be formed, and the flexible film and the printed circuit board are bonded to the back surface of the display panel PN. In this case, a size of the non-display area NA of the front surface of the display panel PN may be reduced to a minimum size. In other words, when the gate driver 30, the data driver 40, and the timing controller 20 are connected to the display panel PN using the above scheme, a zero bezel in which a bezel is substantially absent may be realized.

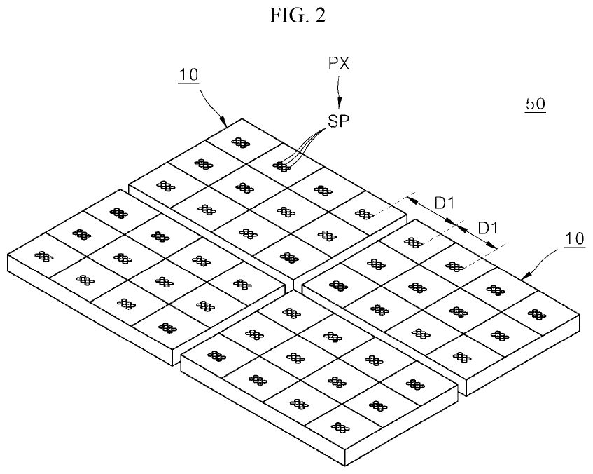

FIG. 2 is a perspective view of a tiling display apparatus 50 according to one or more embodiments of the present disclosure.

Referring to FIG. 2, a light-emitting diode may be disposed in each pixel PX of the display apparatus 10 according to an embodiment of the present disclosure. A pixel PX is an individual unit that emits light and may include a plurality of light-emitting elements and a plurality of pixel circuits for individually driving the plurality of light-emitting elements.

Referring to FIG. 2, a tiling display apparatus 50 with a large screen may be implemented by connecting a plurality of display apparatus 10 to each other. In this regard, as shown in FIG. 2, when the tiling display apparatus 50 is implemented using the display apparatus 10 having a minimized or at least reduced bezel, a seam area between adjacent display apparatus 10 in which an image is not displayed may be minimized or at least reduced such that display quality may be improved.

For example, the plurality of sub-pixels SP may constitute one pixel PX, and a spacing D1 between the outermost pixel PX of one display apparatus 10 and the outermost pixel PX of another display apparatus 10 adjacent thereto may be equal to a spacing D1 between adjacent pixels PX within one display apparatus 10. Accordingly, the spacings between the pixels PX of adjacent display apparatus 10 and the spacings between the pixels PX in the display apparatus 10 may be constant, thereby minimizing or at least reducing the seam area and thus implementing a seamless tiling display apparatus 50.

However, FIG. 2 is merely an example, and the display apparatus 10 according to one embodiment of the present disclosure may be a general display apparatus 10 with a bezel. However, embodiments of the present disclosure are not limited thereto.

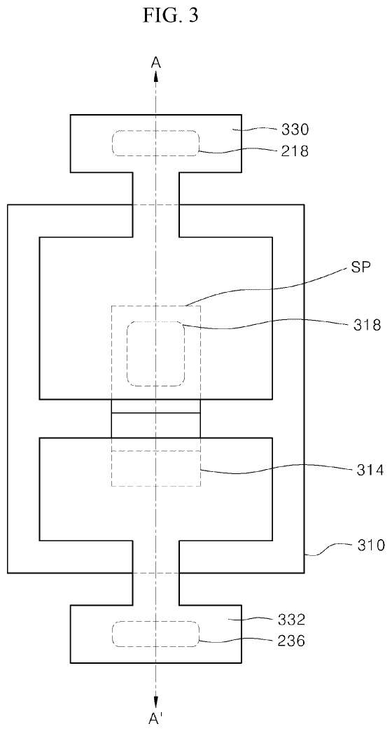

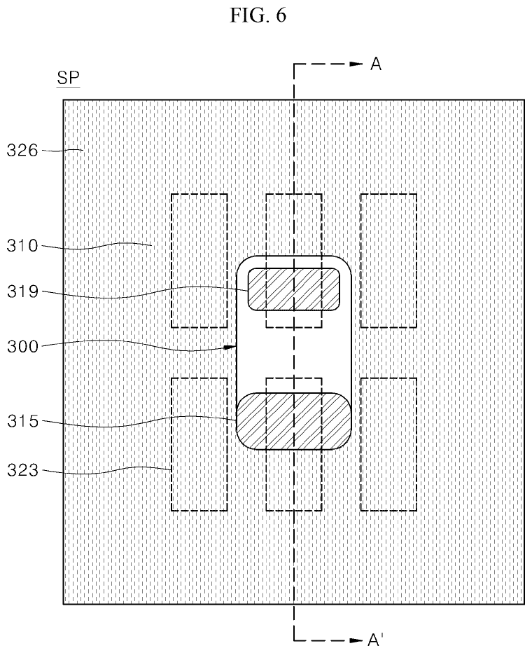

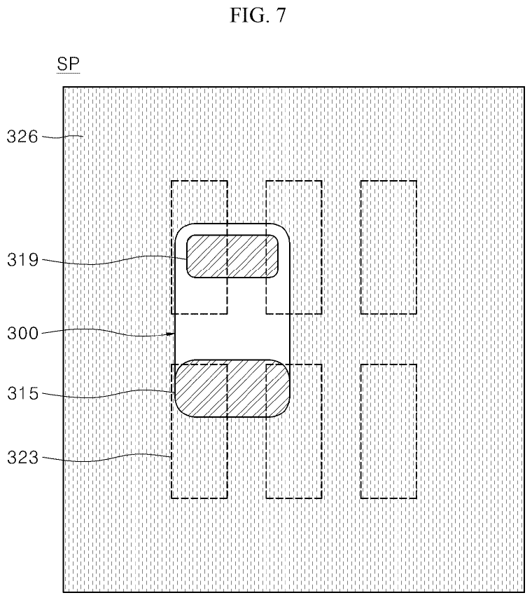

FIGS. 3 to 5 are plan views of a display apparatus according to one or more embodiments of the present disclosure. FIG. 6 and FIG. 7 are plan views of a display apparatus according to one or more other embodiments of the present disclosure. In FIGS. 3 to 7, only some components of the pixel PX among the components of the display apparatus are shown for convenience of illustration. For example, FIGS. 3 to 7 are plan views showing a light-emitting diode 300 and a structure around the light-emitting diode 300.

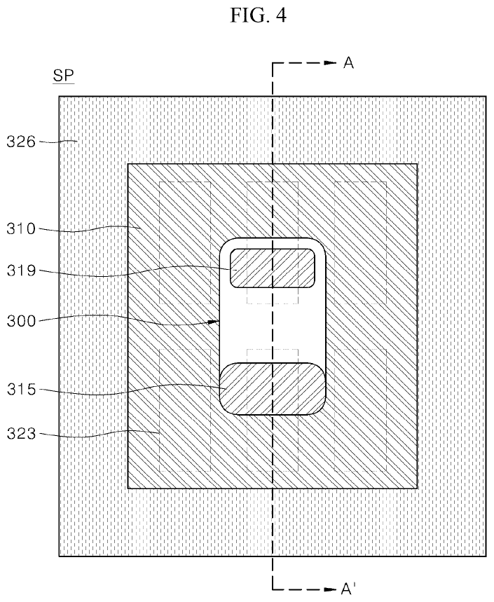

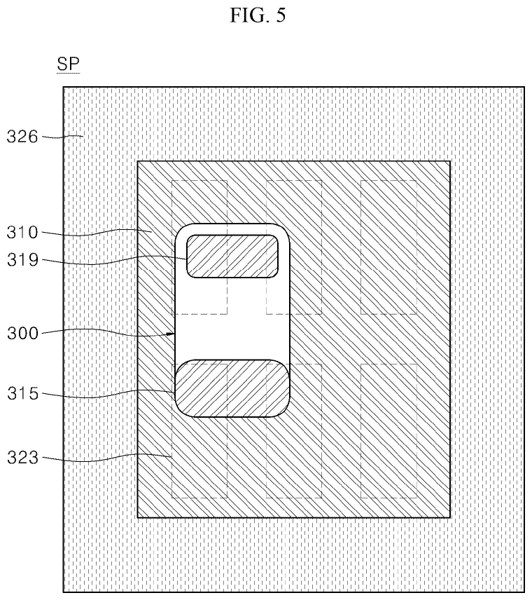

FIG. 4 and FIG. 5 are plan views of a state in which the light-emitting diode 300 has been transferred onto a display panel of a display apparatus according to one or more embodiments of the present disclosure. FIG. 6 and FIG. 7 are plan views of a state in which the light-emitting diode 300 has been transferred onto a display panel of a display apparatus according to one or more other embodiments of the present disclosure. Referring to FIGS. 4 to 7, a second bank 326 may be disposed on top of a reflective layer 310. The second bank 326 may be disposed around the light-emitting diode 300 including an n-type electrode 315 and a p-type electrode 319. The light-emitting diode 300 may be disposed between holes 323 defined in a second insulating layer. Even when the light-emitting diode 300 has a transfer tolerance, the n-type electrode 315 and the p-type electrode 319 may be electrically connected to a first connection electrode 330 and a second connection electrode 332 via the holes 323 formed in the second insulating layer, respectively. A shape of the hole 323 defined in the second insulating layer may be symmetrical, asymmetrical, a single hole, etc. However, embodiments of the present disclosure are not limited thereto.

FIG. 8 is a cross-sectional view of a display apparatus according to one or more embodiments of the present disclosure. FIG. 8 is a cross-sectional view cut alone a line A-A′ shown in FIG. 3, FIG. 4, and FIG. 6.

Referring to FIG. 3 and FIG. 8, each of the plurality of sub-pixels SP of the display panel of the display apparatus according to one or more embodiments of the present disclosure may include a substrate 110, a driving transistor 200, and the light-emitting diode 300. The substrate 110 is a component for supporting various components included in the display apparatus 10 and may be made of an insulating material. For example, the substrate 110 may be made of glass or resin. Further, the substrate 110 may be made of polymers or plastic, and may be made of a material with flexibility. The display apparatus according to one or more embodiments of the present disclosure may operate in a top emission manner in which the emitted light is emitted toward a top of the display apparatus. Accordingly, the substrate 110 may be made of an opaque material as well as a transparent material.

A light-blocking layer 210 may be disposed on the substrate 110 and in each of the plurality of sub-pixels SP. The light-blocking layer 210 may prevent light incident from a position under the substrate 110 from invading a semiconductor layer 214 of the driving transistor 200, which will be described later. The light-blocking layer 210 may prevent the light from being incident to the semiconductor layer 214 of the driving transistor 200, thereby minimizing or at least reducing leakage current.

A buffer layer 112 may be disposed on the substrate 110 and the light-blocking layer 210. The buffer layer 112 may reduce the permeation of moisture or impurities through the substrate 110. The buffer layer 112 may be composed of, for example, a single layer or a multi-layer made of silicon oxide (SiOₓ) or silicon nitride (SiNₓ). However, embodiments of the present disclosure are not limited thereto. However, the buffer layer 112 may be omitted depending on a type of the substrate 110 or a type of the transistor. However, embodiments of the present disclosure are not limited thereto.

The driving transistor 200 may be disposed on the buffer layer 112. The driving transistor 200 includes the semiconductor layer 214, a gate electrode 220, a source electrode 218, and a drain electrode 216.

The semiconductor layer 214 may be disposed on the buffer layer 112. The semiconductor layer 214 may be made of a semiconductor material such as oxide semiconductor, amorphous silicon, or polysilicon. However, embodiments of the present disclosure are not limited thereto.

A gate insulating layer 114 may be disposed on the semiconductor layer 214. The gate insulating layer 114 is an insulating layer for insulating the semiconductor layer 214 and the gate electrode 220 from each other, and may be composed of a single layer or a multi-layer made of silicon oxide (SiOx) or silicon nitride (SiNx). However, embodiments of the present disclosure are not limited thereto.

The gate electrode 220 may be disposed on the gate insulating layer 114. The gate electrode 220 may be made of a conductive material such as copper (Cu), aluminum (Al), molybdenum (Mo), nickel (Ni), titanium (Ti), chromium (Cr), or an alloy thereof. However, embodiments of the present disclosure are not limited thereto.

A first interlayer insulating layer 116 and a second interlayer insulating layer 118 are disposed on the gate electrode 220. The first interlayer insulating layer 116 and the second interlayer insulating layer 118 may have second and third contact-holes 224 and 226 defined therein for respectively connecting the source electrode 218 and the drain electrode 216 to the semiconductor layer 214. Each of the first interlayer insulating layer 116 and the second interlayer insulating layer 118 acts as an insulating layer for protecting components under the first interlayer insulating layer 116 and the second interlayer insulating layer 118, and may be composed of a single layer or double layers made of silicon oxide (SiOx) or silicon nitride (SiNx). However, embodiments of the present disclosure are not limited thereto.

The source electrode 218 and the drain electrode 216 electrically connected to the semiconductor layer 214 may be disposed on the second interlayer insulating layer 118. Each of the source electrode 218 and the drain electrode 216 may be made of a conductive material such as copper (Cu), aluminum (Al), molybdenum (Mo), nickel (Ni), titanium (Ti), chromium (Cr), or an alloy thereof. However, embodiments of the present disclosure are not limited thereto.

The present disclosure describes an example in which the first interlayer insulating layer 116 and the second interlayer insulating layer 118, that is, a plurality of insulating layers are disposed between the gate electrode 220 and the source electrode 218, and the drain electrode 216. However, embodiments of the present disclosure are not limited thereto. Only one insulating layer may be disposed between the gate electrode 220 and the source electrode 218, and the drain electrode 216.

Further, when, as shown in FIG. 8, the plurality of insulating layers such as the first interlayer insulating layer 116 and the second interlayer insulating layer 118 are disposed between the gate electrode 220 and the source electrode 218, and the drain electrode 216, an electrode may be additionally formed between the first interlayer insulating layer 116 and the second interlayer insulating layer 118. The additionally formed electrode and another component disposed under the first interlayer insulating layer 116 or on top of the second interlayer insulating layer 118 may constitute a capacitor.

An auxiliary electrode 212 may be disposed on the gate insulating layer 114. The auxiliary electrode 212 acts as an electrode that electrically connects the light-blocking layer 210 disposed under the buffer layer 112 to one of the source electrode 218 and the drain electrode 216 disposed on the second interlayer insulating layer 118. For example, since the light-blocking layer 210 is electrically connected to either the source electrode 218 or the drain electrode 216 via the auxiliary electrode 212 and does not operate as a floating gate, change in a threshold voltage of the driving transistor 200 otherwise caused by the floating light-blocking layer 210 may be minimized or at least reduced. Although it is shown in FIG. 8 that the light blocking layer 210 is connected to the drain electrode 216 via a first contact hole 222 extending through the buffer layer 112 and the gate insulating layer 114 and a fourth contact hole 228 extending through the first interlayer insulating layer 116 and the second interlayer insulating layer 118, embodiments of the present disclosure are not limited thereto. The light blocking layer 210 may be connected to the source electrode 218. However, embodiments of the present disclosure are not limited thereto. For example, the light blocking layer 210 may overlap at least one of the gate electrode 220, the semiconductor layer 214, the source electrode 218, and the drain electrode 216. For example, the light blocking layer 210 may extend so as to overlap one side and the other side of the semiconductor layer 214.

The source electrode 218, the drain electrode 216, the first power line 232, and the second power line 230 may be disposed on the second interlayer insulating layer 118. The first power line 232 may be electrically connected to the light-emitting diode 300 and the driving transistor 200 to cause the light-emitting diode 300 to emit light. Each of the first power line 232 and the second power line 230 may be made of a conductive material, for example, copper (Cu), aluminum (Al), molybdenum (Mo), nickel (Ni), titanium (Ti), chromium (Cr), or an alloy thereof. However, embodiments of the present disclosure are not limited thereto. The first power line 232 may be spaced apart from the second power line 230.

A third interlayer insulating layer 120 may be disposed on the driving transistor 200, the first power line 232, and the second power line 230. The third interlayer insulating layer 120 may be disposed on the source electrode 218 and the drain electrode 216. The third interlayer insulating layer 120 may be an insulating layer to protect the structure under the third interlayer insulating layer 120. The third interlayer insulating layer 120 may be composed of a single layer or multiple layers made of silicon oxide (SiOₓ) or silicon nitride (SiNₓ). However, embodiments of the present disclosure are not limited thereto.

A planarization layer 124 may be disposed on the third interlayer insulating layer 120. The planarization layer 124 may planarize a top of a portion on top of the substrate 110 in which the driving transistor 200 is disposed. In one or more embodiments of the present disclosure, the planarization layer 124 includes a single layer. However, embodiments of the present disclosure are not limited thereto. For example, the planarization layer 124 may include a plurality of planarization layers. When the planarization layer 124 is composed of the plurality of planarization layers, at least one of the plurality of planarization layers may be composed of a single layer or a double layer. The planarization layer 124 may be made of, for example, photoresist or an acryl-based organic material. However, embodiments of the present disclosure are not limited thereto. The planarization layer 124 may be a protective layer. However, embodiments of the present disclosure are not limited thereto.

A plurality of reflective electrodes 234 and 236 spaced apart from each other may be disposed on the planarization layer 124. The plurality of reflective electrodes 234 and 236 electrically connect the light-emitting diode 300 to the first power line 232 and the driving transistor 200, and may reflect the light emitted from the light-emitting diode 300 therefrom so as to be directed upwardly of the light-emitting diode 300. Each of the plurality of reflective electrodes 234 and 236 may be made of a conductive material with excellent reflective properties and may reflect light emitted from the light-emitting diode 300 therefrom so as to be directed upwardly of the light-emitting diode 300.

The plurality of reflective electrodes 234 and 236 may include the first reflective electrode 234 and the second reflective electrode 236. The first reflective electrode 234 may electrically connect the driving transistor 200 and the light-emitting diode 300 to each other. The first reflective electrode 234 may be connected to the source electrode 218 or the drain electrode 216 of the driving transistor 200 via a sixth contact hole 238 extending through the planarization layer 124. The first reflective electrode 234 may be electrically connected to the p-type electrode 319 of the light-emitting diode 300 and the semiconductor layer 214 via the first connection electrode 330, which will be described later. The first reflective electrode 234 may extend so as to overlap one side and the other side of the light-emitting diode 300. For example, the first reflective electrode 234 may be disposed to overlap a portion of the second bank 326. The first reflective electrode 234 may overlap the second power line 230.

The second reflective electrode 236 may electrically connect the first power line 232 and the light-emitting diode 300 to each other. The second reflective electrode 236 may be connected to the first power line 232 via a seventh contact hole 240 extending through the planarization layer 124, and may be electrically connected to the n-type electrode 315 of the light-emitting diode 300 via the second connection electrode 332, which will be described later.

The reflective layer 310 may be disposed on the plurality of reflective electrodes 234 and 236. The reflective layer 310 may overlap a portion of the first reflective electrode 234.

A fourth interlayer insulating layer 122 may be disposed on the reflective layer 310. The fourth interlayer insulating layer 122 may be an insulating layer to protect the structure under the fourth interlayer insulating layer 122. The fourth interlayer insulating layer 122 may be composed of a single layer or multiple layers made of silicon oxide (SiOₓ) or silicon nitride (SiNₓ). However, embodiments of the present disclosure are not limited thereto.

An adhesive layer 312 may be disposed on the fourth interlayer insulating layer 122. The adhesive layer 312 may adhere or fix the light-emitting diode 300 disposed on the adhesive layer 312. The adhesive layer 312 may be made of, for example, adhesive polymer, epoxy resin, UV resin, polyimide, acryl, urethane, or polydimethylsiloxane (PDMS). However, embodiments of the present disclosure are not limited thereto.

A plurality of light-emitting diodes 300 may be disposed on the adhesive layer 312 in a corresponding manner to the plurality of sub-pixels SP. Each of the plurality of light-emitting diodes 300 refers to a light-emitting element that emits light using electric current. The plurality of light-emitting diodes 300 may emit light beams of various colors including red light, green light, and blue light, and a combination thereto as white light, respectively. However, embodiments of the present disclosure are not limited thereto.

The light-emitting diode 300 may include an n-type semiconductor layer 314, a light-emitting layer 316, a p-type semiconductor layer 318, an n-type electrode 315, and a p-type electrode 319.

The n-type semiconductor layer 314 may be disposed on the adhesive layer 312, and the p-type semiconductor layer 318 may be disposed on the n-type semiconductor layer 314. The n-type semiconductor layer 314 and the p-type semiconductor layer 318 may be layers formed by doping n-type and p-type impurities into a specific material, respectively. For example, each of the n-type semiconductor layer 314 and the p-type semiconductor layer 318 may be each layer doped with each of the n-type and p-type impurities into a matrix made of gallium nitride (GaN), indium aluminum phosphide (InAlP), or gallium arsenide (GaAs). In this regard, the p-type impurity may be magnesium (Mg), zinc (Zn), beryllium (Be), etc., and the n-type impurity may be silicon (Si), germanium (Ge), tin (Sn), etc. However, embodiments of the present disclosure are not limited thereto.

The light-emitting layer 316 may be disposed between the n-type semiconductor layer 314 and the p-type semiconductor layer 318. The light-emitting layer 316 may receive holes and electrons from the n-type semiconductor layer 314 and the p-type semiconductor layer 318 and may emit light under recombination of holes and electrons. The light-emitting layer 316 may be composed of a single-layer or a multi-quantum well (MQW) structure, and may be made of, for example, indium gallium nitride (InGaN) or gallium nitride (GaN). However, embodiments of the present disclosure are not limited thereto.

The n-type electrode 315 may be disposed on the n-type semiconductor layer 314. The n-type electrode 315 may be an electrode for electrically connecting the driving transistor 200 and the n-type semiconductor layer 314 to each other. The n-type electrode 315 may be disposed on an exposed portion of an upper surface of the n-type semiconductor layer 314 not covered with the light-emitting layer 316 and the p-type semiconductor layer 318. For example, the n-type electrode 315 may be disposed along an edge area of the upper surface of the n-type semiconductor layer 314, and may have a circular shape in a plan view thereof. However, embodiments of the present disclosure are not limited thereto. The n-type electrode 315 may be made of a conductive material, for example, a transparent conductive material such as ITO (Indium Tin Oxide) or IZO (Indium Zinc Oxide), or an opaque conductive material such as titanium (Ti), gold (Au), silver (Ag), copper (Cu), or an alloy thereof. However, embodiments of the present disclosure are not limited thereto.

The p-type electrode 319 may be disposed on the p-type semiconductor layer 318. The p-type electrode 319 may be disposed on the upper surface of the p-type semiconductor layer 318. The p-type electrode 319 may be an electrode for electrically connecting the first power line 232 and the p-type semiconductor layer 318 to each other. The p-type electrode 319 may be made of a conductive material, for example, a transparent conductive material such as ITO (Indium Tin Oxide) or IZO (Indium Zinc Oxide), or an opaque conductive material such as titanium (Ti), gold (Au), silver (Ag), copper (Cu), or an alloy thereof. However, embodiments of the present disclosure are not limited thereto.

According to one or more embodiments of the present disclosure, the display apparatus 100 comprises: a substrate 110 includes pixel; a light-emitting diode 300 disposed in the pixel; a first insulating layer 320 disposed around the light-emitting diode 300; a second insulating layer 322 disposed on the first insulating layer 320; and a first bank 324 disposed around the second insulating layer 322.

According to one or more other embodiments of the present disclosure, the light-emitting diode 300 may have a structure different from a structure of a lateral type light-emitting diode 300. A first insulating layer 320 may be located on a side surface of the plurality of light-emitting diode 300. A second insulating layer 322 and a third insulating layer 328 may be disposed to cover the plurality of light-emitting diodes 300, and may fix and/or protect the plurality of light-emitting diodes 300. Each of the first insulating layer 320, the second insulating layer 322, and the third insulating layer 328 may be composed of a single layer or a stack of multiple layers made of silicon oxide (SiOₓ) or silicon nitride (SiNₓ). However, embodiments of the present disclosure are not limited thereto.

A first bank 324 may be disposed on the first insulating layer 320. The second insulating layer 322 may be disposed on a side surface of the first bank 324. The third insulating layer 328 may be disposed on the first bank 324 and the second insulating layer 322.

A second bank 326 may be disposed on the first insulating layer 320. The second insulating layer 322 may be disposed on a side surface of the second bank 326. The third insulating layer 328 may be disposed on the second bank 326 and the second insulating layer 322.

After forming or depositing the second insulating layer 322, a plurality of connection electrodes may be formed. The plurality of connection electrodes may include the first connection electrode 330 and the second connection electrode 332.

The first connection electrode 330 may be an electrode disposed in each of the plurality of sub-pixels SP and may electrically connect the light-emitting diode 300 and the driving transistor 200 to each other. The first connection electrode 330 may be connected to the first reflective electrode 234 via an eighth contact hole 242 extending through the fourth interlayer insulating layer 122, the first insulating layer 320, and the second insulating layer 322. The first connection electrode 330 may be formed along a side surface of the second insulating layer 322.

The first connection electrode 330 may be electrically connected to one of the source electrode 218 and the drain electrode 216 of the driving transistor 200 via the first reflective electrode 234. The first connection electrode 330 may be connected to the p-type electrode 319 of each of the plurality of light-emitting diodes 300. Accordingly, the first connection electrode 330 may electrically connect the driving transistor 200 to the p-type electrode 319 and the p-type semiconductor layer 318 of each of the plurality of light-emitting diodes 300.

The second connection electrode 332 may be an electrode for electrically connecting the light-emitting diode 300 and the first power line 232 to each other. The second connection electrode 332 may be connected to the second reflective electrode 236 via a ninth contact hole 244 extending through the fourth interlayer insulating layer 122, and the first and second insulating layers 320 and 322. The second connection electrode 332 may be formed along a side surface of the second insulating layer 322.

The second connection electrode 332 may be electrically connected to the first power line 232 via the second reflective electrode 236. The second connection electrode 332 may be connected to the n-type electrode 315 of each of the plurality of light-emitting diodes 300. Accordingly, the second connection electrode 332 may electrically connect the first power line 232 to the n-type electrode 315 and the n-type semiconductor layer 314 of each of the plurality of light-emitting diodes 300.

The first connection electrode 330 disposed in each of the plurality of sub-pixels SP so as to connect the driving transistor 200 and the light-emitting diode 300 to each other may be individually disposed in each of the plurality of sub-pixels SP. The second connection electrode 332 may be disposed in each of the plurality of sub-pixels SP so as to connect the first power line 232 and the light-emitting diode 300 to each other. In this regard, the second connection electrodes 332 respectively disposed in adjacent ones of the plurality of sub-pixels SP may be connected to each other. For example, since the power voltage of the first power line 232 is commonly applied to all of the plurality of light-emitting diodes 300 of the plurality of sub-pixels SP, a single integrated second connection electrode 332 may be disposed throughout the plurality of sub-pixels SP.

The first bank 324 and the second bank 326 may be formed on the first connection electrode 330 and the second connection electrode 332.

The first bank 324 may be disposed on top of the driving transistor 200. The first bank 324 may cover at least a portion of the first connection electrode 330 and at least a portion of the second connection electrode 332. A vertical level of an upper surface SS2 of the first bank 324 may be lower than a vertical level of an upper surface SS1 of the light-emitting diode 300. For example, the vertical level of the upper surface SS2 of the first bank 324 may be lower than a vertical level of a top of the first connection electrode 330.

The light emitted from the light-emitting diode 300 may be emitted in all directions from the light-emitting layer 316, and thus may include top-directed light 8a, reflected top-directed light 8a′, side-directed light 8b and 8b′, first reflected side-directed light 8c and 8c′, and second reflected side-directed light 8d and 8d′.

The top-directed light 8a may be light output from the light-emitting diode 300 in an upward direction to the top of the display apparatus. The reflected top-directed light 8a′ may be light output from the light-emitting diode 300 in a downward direction, then reflected from the reflective layer 310, and output in the upward direction to the top of the display apparatus. The side-directed light 8b and 8b′ may be light output from the light-emitting diode 300 in upward and right and left directions, respectively. The first reflected side-directed light 8c and 8c′ may be light output from the light-emitting diode 300 in a downward direction, then reflected from the reflective layer 310, and output in upward and right and left directions, respectively. The second reflected side-directed light 8d and 8d′ may be light output from the light-emitting diode 300 in a downward direction, then reflected from the reflective layer 310, and output in upward and right and left directions, respectively and then may be absorbed by the second bank 326.

In FIG. 8, the light emitted from the light-emitting diode 300 includes the top-directed light 8a, the reflected top-directed light 8a′, the side-directed light 8b and 8b′, the first reflected side-directed light 8c and 8c′, and the second reflected side-directed light 8d and 8d′ as represented by one or more arrows. However, embodiments of the present disclosure are not limited thereto. The light emitted from the light-emitting diode 300 may include light beams having travel directions other than the directions as represented by one or more arrows.

The reflective layer 310 may be formed to extend so as to overlap one side and the other side of the light-emitting diode 300. The reflective layer 310 may overlap a portion of the second bank 326.

The second bank 326 may be disposed around the light-emitting diode 300. For example, the second bank 326 may be disposed around the light-emitting diode 300 so that a light-emitting area of the light-emitting diode 300 is open. As a result, the second bank 326 may absorb the second reflected side-directed light 8d and 8d′ reflected from the reflective layer 310. Therefore, since the loss of light output from the light-emitting diode 300 is small, such that luminance of light in a frontward direction of the display apparatus may be improved.

A vertical level of a top of the second bank 326 may be equal to or different from a vertical level of a top of each of the first connection electrode 330 or the second connection electrode 332. In one example, the vertical level of the top of the second bank 326 may be lower than the vertical level of the top of each of the first connection electrode 330 or the second connection electrode 332.

The second bank 326 may be disposed in a fifth contact hole 229 defined in the second insulating layer 322. The second bank 326 may be disposed on the first connection electrode 330 or the second connection electrode 332 formed along a bottom surface and a side surface of the fifth contact hole 229. The second bank 326 may be configured to fill at least a portion of the fifth contact hole 229. Therefore, the second reflected side-directed light 8d and 8d′ of the light of the light-emitting diode 300 may be absorbed by the second bank 326.

Each of the first bank 324 and the second bank 326 may be made of an organic film such as acryl resin, epoxy resin, phenolic resin, polyamide resin, or polyimide resin. However, embodiments of the present disclosure are not limited thereto. Each of the first bank 324 and the second bank 326 may include a black material that absorbs light. Accordingly, the light emitted from the light-emitting diode 300 provided in each sub-pixel SP may be absorbed with the first bank 324 and the second bank 326 and may not be emitted to an outside in an area in which the first bank 324 and the second bank 326 are formed. Accordingly, the area where the first bank 324 and the second bank 326 are formed may correspond to a non-light-emitting area. The first bank 324 and the second bank 326 prevent the light emitted from the light-emitting diode 300 in one sub-pixel SP from traveling to another sub-pixel SP adjacent thereto. Thus, color mixing between light beams from the sub-pixels SP may be prevented or at least reduced. For example, the first bank 324 may be a first black layer or a first light blocking layer. However, embodiments of the present disclosure are not limited thereto. For example, the second bank 326 may be a second black layer or a second light blocking layer. However, embodiments of the present disclosure are not limited thereto.

In the display apparatus according to one or more embodiments of the present disclosure, the second bank 326 may be located on sides of the light-emitting diode 300 and may absorb the second reflected side-directed light beams 8d and 8d′ among the light beams emitted from the light-emitting diode 300. As a result, the display apparatus according to one or more embodiments of the present disclosure may minimize or at least reduce a visibility difference due to the reflected light.

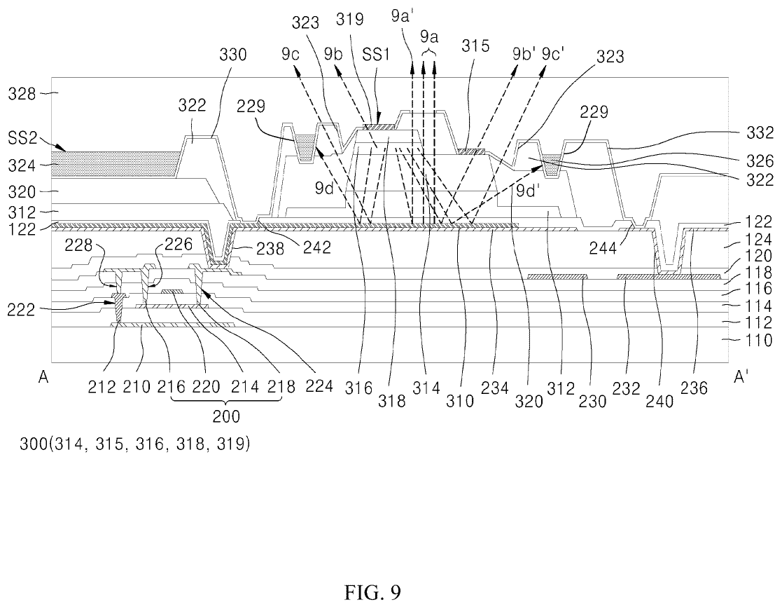

FIG. 9 is a cross-sectional view of a display apparatus according to one or more other embodiments of the present disclosure. Since the descriptions of the substrate 110, the driving transistor 200, and the light-emitting diode 300 in FIG. 9 are the same as those as set forth above with reference to FIG. 8, the same reference numerals as those in FIG. 8 are assigned to the components thereof, and duplicate descriptions thereof are omitted or the descriptions thereof are simplified.

Referring to FIG. 9, the light emitted from the light-emitting diode 300 may include top-directed light 9a, reflected top-directed light 9a′, side-directed light 9b and 9b′, first reflected side-directed light 9c and 9c′, and second reflected side-directed light 9d and 9d′.

The top-directed light 9a may be light output from the light-emitting diode 300 in an upward direction to the top of the display apparatus. The reflected top-directed light 9a′ may be light output from the light-emitting diode 300 in a downward direction, then reflected from the reflective layer 310, and output in the upward direction to the top of the display apparatus. The side-directed light 9b and 9b′ may be light output from the light-emitting diode 300 in upward and right and left directions, respectively. The first reflected side-directed light 9c and 9c′ may be light output from the light-emitting diode 300 in a downward direction, then reflected from the reflective layer 310, and output in upward and right and left directions, respectively. The second reflected side-directed light 9d and 9d′ may be light output from the light-emitting diode 300 in a downward direction, then reflected from the reflective layer 310, and output in upward and right and left directions, respectively and then may be absorbed by the second bank 326.

As shown in FIG. 9, the fifth contact hole 229 extends through the second insulating layer 322 and extends through a part of the first insulating layer. The second bank 326 may be disposed on the first connection electrode 330 or the second connection electrode 332 disposed in the fifth contact hole 229. The second bank 326 may be configured to fill at least a portion of the fifth contact hole 229. Therefore, the second reflected side-directed light beams 9d and 9d′ among the light beams of the light-emitting diode 300 may be absorbed by the second bank 326.

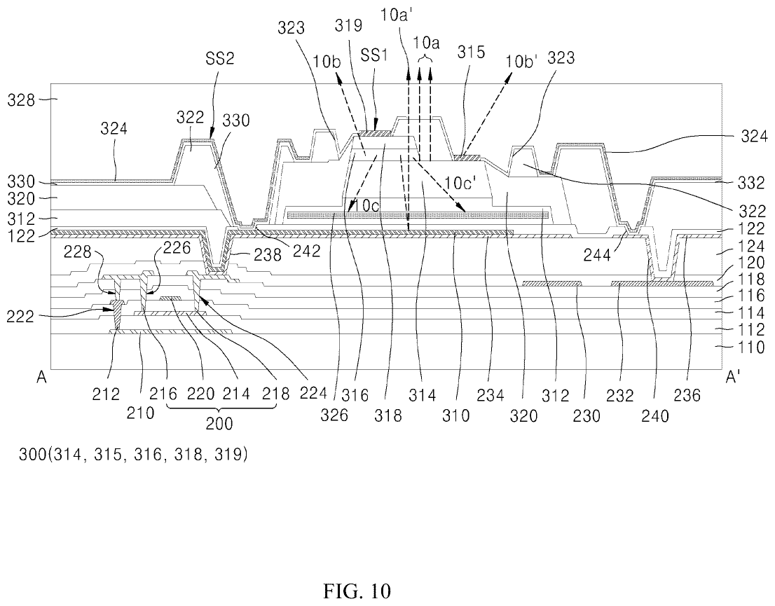

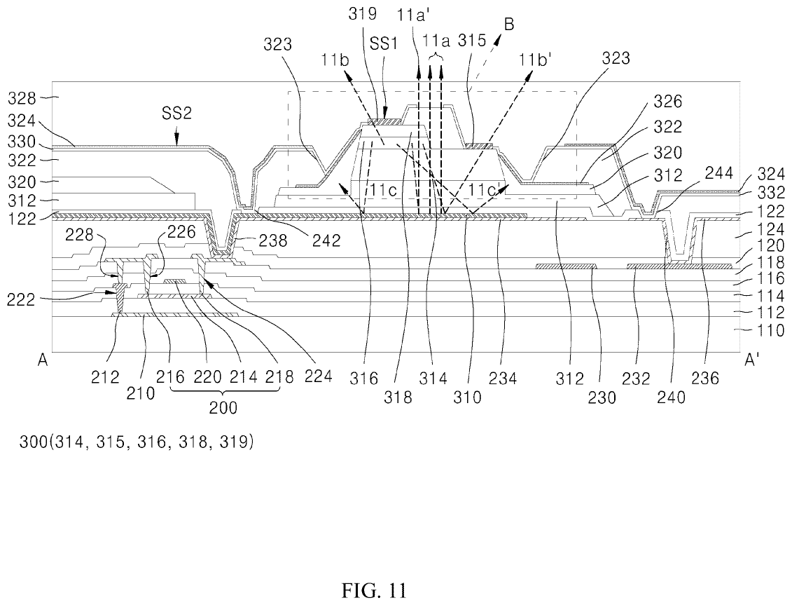

FIG. 10 and FIG. 11 are cross-sectional views of display apparatus according to one or more other embodiments of the present disclosure. Since the descriptions of the substrate 110, the driving transistor 200, and the light-emitting diode 300 in each of FIG. 10 and FIG. 11 are the same as those as set forth above with reference to FIG. 8, the same reference numerals as those in FIG. 8 are assigned to the components thereof, and duplicate descriptions thereof are omitted or the descriptions thereof are simplified.

Referring to FIG. 10, the first bank 324 may be formed around the side surface of the light-emitting diode 300. The first bank 324 may be disposed to cover at least a portion of each of the first connection electrode 330 and the second connection electrode 332. For example, the first bank 324 may be disposed on top of the driving transistor 200. The first bank 324 may be disposed on the second connection electrode 330. A vertical level of the top surface SS2 of the first bank may be lower than a vertical level of the top surface SS1 of the light-emitting diode 300.

The light output from the light-emitting diode 300 may include top-directed light 10a, reflected top-directed light 10a′, side-directed light 10b and 10b′, and bottom-directed light 10c and 10c′. The top-directed light 10a may be light output from the light-emitting diode 300 in an upward direction to the top of the display apparatus. The reflected top-directed light 10a′ may be light output from the light-emitting diode 300 in a downward direction, then reflected from the reflective layer 310, and output in the upward direction to the top of the display apparatus. The side-directed light 10b and 10b′ may be light output from the light-emitting diode 300 in upward and right and left directions, respectively. The bottom-directed light 10c and 10c′ may be light output from the light-emitting diode 300 in a downward direction.

In FIG. 10, the light emitted from the light-emitting diode 300 includes the top-directed light 10a, the reflected top-directed light 10a′, side-directed light 10b and 10b′, and the bottom-directed light 10c and 10c′ as represented by one or more arrows. However, embodiments of the present disclosure are not limited thereto. The light emitted from the light-emitting diode 300 may include light beams having travel directions other than the directions as represented by one or more arrows.

The fourth interlayer insulating layer 122 and the adhesive layer 312 may be disposed on the reflective layer 310. The second bank 326 may be disposed on the fourth interlayer insulating layer 122. The second bank 326 may overlap the reflective layer 310. For example, in a plan view, an area size of the reflective layer 310 may be larger than that of the second bank 326. The second bank 326 may overlap the second reflective electrode 234. For example, in the plan view, the area size of the second bank 326 may be smaller than that of the second reflective electrode 234. The second bank 326 may overlap a portion of the first bank 324. For example, the second bank 326 may extend so as to overlap an area outside the light-emitting diode 300. Each of both opposing ends of the second bank 326 may overlap a portion of the first bank 324. Therefore, the bottom-directed light beams 10c and 10c′ among the light beams emitted from the light-emitting diode 300 may be absorbed by the second bank 326, and thus the luminance difference or deviation according to the viewing angle may be reduced.

Referring to FIG. 11, the side surface of the light-emitting diode 300 may contact the first insulating layer 320, the second bank 326, the first connection electrode 330, and the second connection electrode 332. The fourth interlayer insulating layer 122 and the adhesive layer 312 may be disposed on the reflective layer 310. The reflective layer 310 may overlap the light-emitting diode 300 and may overlap a portion of the second bank 326. The first bank 324 may be disposed on the second insulating layer 322. The first bank 324 may be disposed on the first connection electrode 330. A vertical level of the upper surface SS2 of the first bank 324 may be lower than the vertical level of the upper surface SS1 of the light-emitting diode 300. The first connection electrode 330 may be connected to the first reflective electrode 234 via the eighth contact hole 242 extending through the fourth interlayer insulating layer 122 and the second insulating layer 322. The first connection electrode 330 may be formed along the side surface of the second insulating layer 322.

The second bank 326 may be disposed on the first insulating layer 320.

Referring to FIG. 11, the light emitted from the light-emitting diode 300 may include top-directed light 11a, reflected top-directed light 11a′, side-directed light 11b and 11b′, and reflected side-directed light 11c and 11c′.

The top-directed light 11a may be light output from the light-emitting diode 300 in an upward direction to the top of the display apparatus. The reflected top-directed light 11a′ may be light output from the light-emitting diode 300 in a downward direction, then reflected from the reflective layer 310, and output in the upward direction to the top of the display apparatus. The side-directed light 11b and 11b′ may be light output from the light-emitting diode 300 in upward and right and left directions, respectively. The reflected side-directed light 11c and 11c′ may be light output from the light-emitting diode 300 in a downward direction, then reflected from the reflective layer 310, and output in upward and right and left directions, respectively and then may be absorbed by the second bank 326.

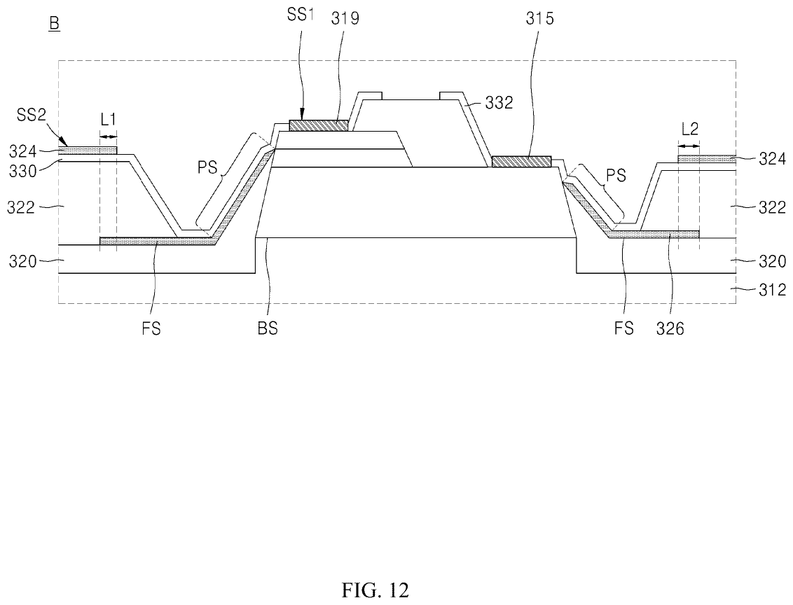

FIG. 12 is an enlarged cross-sectional view of a B portion of FIG. 11 according to one or more other embodiments of the present disclosure.

Referring to FIG. 12, the second bank 326 may be disposed between an end of the upper surface SS1 of the light-emitting diode 300 and an end of the lower surface BS of the light-emitting diode 300. For example, an upper end of the second bank 326 may be disposed between an end of the upper surface SS1 of the light-emitting diode 300 and an end of the lower surface BS of the light-emitting diode 300.

Referring to FIG. 12, a distance between an upper end of one side of the second bank 326 and one side end of the upper surface SS1 of the light-emitting diode 300 may be smaller than a distance between the upper end of one side of the second bank 326 and one side end of the lower surface BS of the light-emitting diode 300. The upper end of a portion of the second bank 326 adjacent to one side of the light-emitting diode 300 may be located at a higher vertical level than a vertical level of the upper end of a portion of the second bank 326 adjacent to the other side of the light-emitting diode 300.

The second bank 326 may include an inclined surface PS and a flat surface FS. A spacing between the inclined surface PS of the second bank 326 and the side surface of the light-emitting diode 300 may vary as the inclined surface PS of the second bank 326 extends from an upper end to a lower end of the inclined surface PS of the second bank 326. For example, the spacing between the inclined surface PS of the second bank 326 and the side surface of the light-emitting diode 300 may increase as the inclined surface PS of the second bank 326 extends from the upper end to the lower end of the inclined surface PS of the second bank 326.

Therefore, the reflected side-directed light beams 11c and 11c′ among the light beams emitted from the light-emitting diode 300 may be absorbed by the inclined surface PS of the second bank 326, and thus the luminance difference or deviation according to the viewing angle may be reduced. For example, the reflected side-directed light beams 11c and 11c′ among the light beams emitted from the light-emitting diode 300 may travel downwardly and then be reflected from the reflective layer 310 and may travel upwardly in a left or right side, and then may be absorbed by the inclined surface PS of the second bank 326, and thus the luminance difference or deviation according to the viewing angle may be reduced.

According to one or more embodiments of the present disclosure, the flat surface FS of the second bank 326 may overlap the first bank 324 in the vertical direction. A first width L1 overlapped by the first bank 324 and the flat surface FS of a portion of the second bank 326 disposed on one side of the light-emitting diode 300 may be equal to or different from a second width L2 overlapped by the first bank 324 and the flat surface FS of a portion of the second bank 326 disposed on the other side of the light-emitting diode 300.

According to one or more embodiments of the present disclosure, a width (or a length) of the inclined surface PS on one side of the second bank 326 and a width (or a length) of the inclined surface PS on the other side of the second bank 326 may be different from each other.

For example, when the second bank 326 is disposed on top of the light-emitting diode 300, a defect may occur when the diode is connected to the second connection electrode 322 or a contact defect thereof with a pad electrode may occur. Accordingly, according to one or more embodiments of the present disclosure, the second bank 326 is not disposed on top of the light-emitting diode 300. Thus, the defect may not occur when the diode is connected to the second connection electrode 322 and/or the contact defect thereof with the pad electrode may be suppressed.

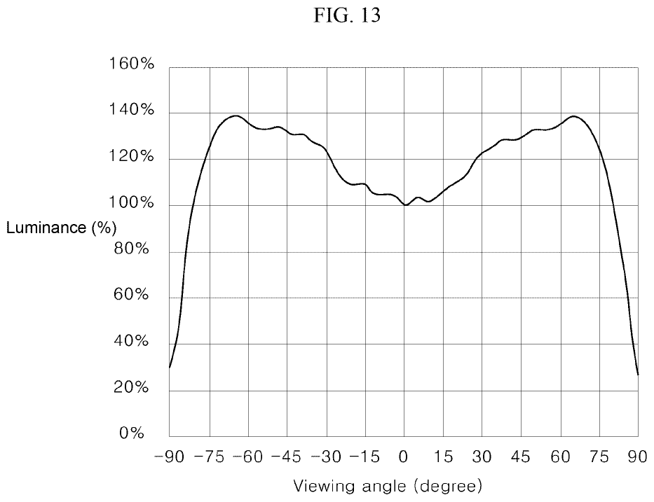

FIGS. 13 to 15 are graphs showing luminance based on a viewing angle of a display apparatus according to one or more embodiments of the present disclosure. For example, FIGS. 13 to 15 are graphs showing the luminance simulation results based on the viewing angle of the display apparatus according to FIG. 8, FIG. 10, and FIG. 11, respectively. Referring to FIGS. 13 to 15, it is assumed that the luminance of light in the frontward direction at a viewing angle of 0 degrees is 100%. The luminance of light at a viewing angle of 60 degrees may be compared with the luminance 100% of light in the frontward direction at a viewing angle of 0 degrees. Thus, luminance deviation between the luminance of light at a viewing angle of 60 degrees and the luminance 100% of light in the frontward direction at a viewing angle of 0 degrees may be obtained.

Referring to FIG. 13, the luminance deviation between the luminance of light at a viewing angle of 60 degrees and the luminance 100% of light in the frontward direction at a viewing angle of 0 degrees is 35%.

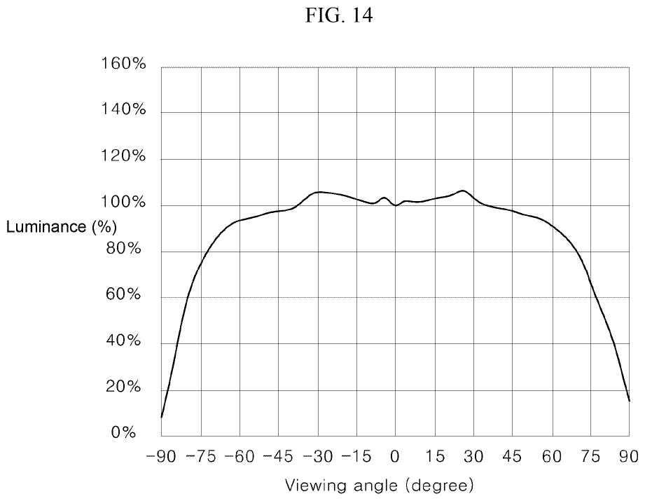

Referring to FIG. 14, the luminance deviation between the luminance of light at a viewing angle of 60 degrees and the luminance 100% of light in the frontward direction at a viewing angle of 0 degrees is 10%. Thus, the display apparatus in FIG. 10 may have reduced luminance deviation between the luminance of light at a viewing angle of 60 degrees and the luminance 100% of light in the frontward direction at a viewing angle of 0 degrees, compared to the display apparatus in FIG. 8.

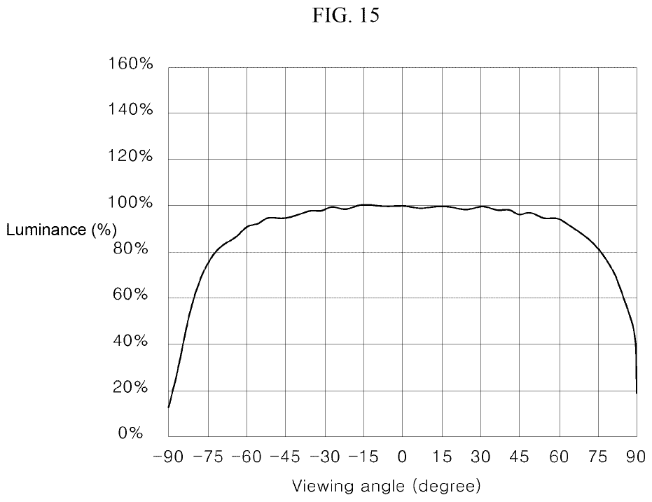

Referring to FIG. 15, the luminance deviation between the luminance of light at a viewing angle of 60 degrees and the luminance 100% of light in the frontward direction at a viewing angle of 0 degrees is 5%. Thus, the display apparatus in FIG. 11 may have reduced luminance deviation between the luminance of light at a viewing angle of 60 degrees and the luminance 100% of light in the frontward direction at a viewing angle of 0 degrees, compared to the display apparatus in FIG. 10.

According to one or more embodiments of the present disclosure, the bank may be disposed around the light-emitting diode, such that the luminance deviation depending on the viewing angle of the display apparatus may be reduced.

A display apparatus according to various embodiments of the present disclosure may be described as follows.

One or more embodiments of the present disclosure provide a display apparatus comprising: a substrate includes pixel; a light-emitting diode disposed in the pixel; a first insulating layer disposed around the light-emitting diode; a second insulating layer disposed on the first insulating layer; and a first bank disposed around the second insulating layer.

In accordance with one or more embodiments of the present disclosure, the display apparatus further comprises a thin-film transistor disposed on the substrate, wherein the first bank covers at least a portion of the thin-film transistor.

In accordance with one or more embodiments of the present disclosure, the display apparatus further comprises: a connection electrode disposed on the first insulating layer; and a second bank disposed on the connection electrode.

In accordance with one or more embodiments of the present disclosure, the display apparatus further comprises a reflective layer disposed under the light-emitting diode.

In accordance with one or more embodiments of the present disclosure, the display apparatus further comprises a hole defined in the second insulating layer, wherein the second bank is disposed in the hole.

In accordance with one or more embodiments of the present disclosure, the display apparatus further comprises a hole extending through a part of the first insulating layer, wherein the second bank is disposed in the hole.

In accordance with one or more embodiments of the present disclosure, a vertical level of a top surface of the first bank is lower than a vertical level of a top surface of the light-emitting diode.

In accordance with one or more embodiments of the present disclosure, the second bank is located on sides of the light-emitting diode.

In accordance with one or more embodiments of the present disclosure, the display apparatus further comprises a connection electrode disposed on the first insulating layer, wherein the first bank is disposed on the connection electrode.

In accordance with one or more embodiments of the present disclosure, the display apparatus further comprises a thin-film transistor disposed on the substrate, wherein the first bank covers the thin-film transistor.

In accordance with one or more embodiments of the present disclosure, the display apparatus further comprises a second bank disposed under the light-emitting diode, wherein the first bank overlaps with both opposing ends of the second bank in upper direction and lower direction.

In accordance with one or more embodiments of the present disclosure, the second bank extends outside of the light-emitting diode.

In accordance with one or more embodiments of the present disclosure, the display apparatus further comprises a second bank disposed on the first insulating layer, wherein the second bank is disposed on a portion of a side surface of the light-emitting diode.

In accordance with one or more embodiments of the present disclosure, the first bank overlaps with a side end of the second bank in upper direction and lower direction.

In accordance with one or more embodiments of the present disclosure, an upper end of the second bank is disposed between an end of an upper surface of the light-emitting diode and an end of a lower surface of the light-emitting diode.

In accordance with one or more embodiments of the present disclosure, a spacing between an upper end of the second bank and an end of an upper surface of the light-emitting diode is smaller than a spacing between the upper end of the second bank and an end of a lower surface of the light-emitting diode.

In accordance with one or more embodiments of the present disclosure, a vertical level of an upper end of a portion of the second bank adjacent to one side of the light-emitting diode is higher than a vertical level of an upper end of a portion of the second bank adjacent to the other side of the light-emitting diode.

In accordance with one or more embodiments of the present disclosure, the display apparatus further comprises a connection electrode disposed on the first insulating layer, wherein a side surface of the light-emitting diode is in contact with the first insulating layer, the second bank, and the connection electrode.

In accordance with one or more embodiments of the present disclosure, the second bank includes an inclined surface and a flat surface connected to each other, wherein a horizontal spacing between the inclined surface and a side surface of the light-emitting diode varies as the inclined surface extends from an upper end to a lower end thereof.

In accordance with one or more embodiments of the present disclosure, the first bank is disposed on the second insulating layer, wherein the second bank is disposed on the first insulating layer.

In accordance with one or more embodiments of the present disclosure, the display apparatus further comprises a reflective layer disposed under the light-emitting diode.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A display apparatus, comprising:
a substrate that includes a pixel;
a light-emitting diode in the pixel;
a first insulating layer around the light-emitting diode;
a second insulating layer on the first insulating layer; and
a first bank around the second insulating layer.

2. The display apparatus of claim 1, further comprising:
a thin-film transistor on the substrate,
wherein the first bank covers at least a portion of the thin-film transistor.

3. The display apparatus of claim 1, further comprising:
a connection electrode on the first insulating layer; and
a second bank on the connection electrode.

4. The display apparatus of claim 1, further comprising:
a reflective layer under the light-emitting diode.

5. The display apparatus of claim 3, further comprising:
a hole in the second insulating layer,
wherein the second bank is in the hole.

6. The display apparatus of claim 3, further comprising:
a hole extending through the second insulating layer and a part of the first insulating layer,
wherein the second bank is in the hole.

7. The display apparatus of claim 1, wherein a first vertical level of a top surface of the first bank is lower than a second vertical level of a top surface of the light-emitting diode.

8. The display apparatus of claim 3, wherein the second bank is on a plurality of sides of the light-emitting diode.

9. The display apparatus of claim 1, further comprising:
a connection electrode on the first insulating layer,
wherein the first bank is on the connection electrode.

10. The display apparatus of claim 9, further comprising:
a thin-film transistor on the substrate,
wherein the first bank covers the thin-film transistor.

11. The display apparatus of claim 9, further comprising:
a second bank under the light-emitting diode,
wherein the first bank overlaps with opposing ends of the second bank in an upper direction and a lower direction that is opposite to the upper direction.

12. The display apparatus of claim 11, wherein the second bank extends outside of the light-emitting diode.

13. The display apparatus of claim 1, further comprising:
a second bank on the first insulating layer, and the second bank is on a portion of a side surface of the light-emitting diode.

14. The display apparatus of claim 13, wherein the first bank overlaps with a side end of the second bank in an upper direction and a lower direction that is opposite to the upper direction.

15. The display apparatus of claim 13, wherein an upper end of the second bank is between an end of an upper surface of the light-emitting diode and an end of a lower surface of the light-emitting diode.

16. The display apparatus of claim 13, wherein a first spacing between an upper end of the second bank and an end of an upper surface of the light-emitting diode is smaller than a second spacing between the upper end of the second bank and an end of a lower surface of the light-emitting diode.

17. The display apparatus of claim 13, wherein a first vertical level of an upper end of a portion of the second bank that is adjacent to a first side of the light-emitting diode is higher than a second vertical level of an upper end of a portion of the second bank that is adjacent to a second side of the light-emitting diode.

18. The display apparatus of claim 13, further comprising:
a connection electrode on the first insulating layer,
wherein a side surface of the light-emitting diode is in contact with the first insulating layer, the second bank, and the connection electrode.

19. The display apparatus of claim 13, wherein the second bank includes an inclined surface and a flat surface that are connected to each other, and
wherein a horizontal spacing between the inclined surface and a side surface of the light-emitting diode varies as the inclined surface extends from an upper end of the inclined surface to a lower end of the inclined surface.

20. The display apparatus of claim 13, wherein the first bank is on the second insulating layer, and
wherein the second bank is on the first insulating layer.

21. The display apparatus of claim 13, further comprising:
a reflective layer under the light-emitting diode.
